(19) United States
(12) Patent Application Publication
(10) Pub. No.: US 2026/0126491 A1
(43) Pub. Date: May 7, 2026

(54) INTELLIGENT POWER MANAGEMENT SYSTEM, INCLUDING AUTONOMOUS BATTERY SELF-CHARACTERIZATION

(71) Applicant: SEMICONDUCTOR COMPONENTS INDUSTRIES, LLC, Scottsdale, AZ (US)

(72) Inventor: Hideo KONDO, Oizumi-machi (JP)

(73) Assignee: SEMICONDUCTOR COMPONENTS INDUSTRIES, LLC, Scottsdale, AZ (US)

(21) Appl. No.: 19/072,300

(22) Filed: Mar. 6, 2025

Related U.S. Application Data
(60) Provisional application No. 63/717,491, filed on Nov. 7, 2024.

(51) Int. Cl. G01R 31/367; G01R 31/378; G01R 31/3842; G01R 31/389; G01R 31/392; G01R 31/396; H01M 10/0525; H01M 10/44; H01M 10/48

(52) U.S. Cl. CPC G01R 31/367; G01R 31/378; G01R 31/3842; G01R 31/389; G01R 31/392; G01R 31/396; H01M 10/0525; H01M 10/44; H01M 10/486; H01M 10/488

(57) ABSTRACT

A system for characterizing a battery of a battery electric system includes a sensor array, processor, and memory. The sensor array measures a temperature-specific battery voltage and battery current of the battery as battery parameters. The processor executes instructions from memory to provide or create a baseline open circuit voltage to state of charge (OCV-SOC) characteristic relationship during a sequence of charging and discharging modes of the battery. After creating or accessing the baseline OCV-SOC characteristic relationship, the processor determines if the battery is in an open mode during which the battery is not connected to a load. In open mode, the battery parameters are measured via the sensor array. An adjusted OCV-SOC characteristic relationship is created by adjusting an SOC quantity of the baseline OCV-SOC characteristic relationship using the battery parameters. The battery is controlled using the adjusted OCV-SOC characteristic relationship.

### CROSS-REFERENCE TO RELATED APPLICATIONS

The present application claims the benefit of priority to U.S. Provisional Application No. 63/717,491 filed Nov. 7, 2024, which is hereby incorporated by reference in its entirety for all purposes.

### INTRODUCTION

The present disclosure relates to electrical circuit topologies and control methods for monitoring parameters of electrochemical batteries for optimal control of the same. Electric vehicles, standby power supplies, power stations, and other mobile and stationary battery electric systems utilize rechargeable batteries as energy storage devices. The rechargeability and high energy storage capacities of lithium-based batteries in particular has led to their widespread adoption in a myriad of different industries. For example, lithium batteries are used to power electric motors in mobile and stationary battery electric systems, and to energize actuators, sensors, displays, and control circuits of a host of medical devices, industrial systems, and consumer products.

Several types of lithium batteries are commercially available and in widespread use. A given application set may use, for instance, lithium cobalt oxide (LCO), lithium nickel manganese cobalt oxide (NMC), lithium iron phosphate (LFP), lithium nickel cobalt aluminum oxide (NCA), lithium manganese oxide (LMO), or other lithium-ion or lithium-based batteries. Each lithium battery type has unique performance characteristics providing relative advantages and disadvantages over competing battery types. As a result, a given battery chemistry may be more or less suitable than others for use in a particular application. Accurate knowledge of the battery type's performance characteristics is thus required for proper selection, monitoring, and ultimate control of a battery for use in a battery electric circuit. However, once a battery is integrated into the battery electric system or other application set, the battery may be difficult to access and remove for the purpose of battery characterization.

### SUMMARY

Disclosed herein are battery monitoring systems and automated methods for monitoring an electrochemical battery for use in a battery electric system. The strategy set forth herein autonomously characterizes a battery while it is in use, i.e., installed in the battery electric system. A battery profile for the installed battery is created in real-time in a possible implementation, without removing the battery and without waiting through an extended relaxation/settling time before ascertaining the battery's open circuit voltage (OCV). Instead, autonomous characterization is achieved via programming of an electronic battery monitoring unit (BMU), which updates the state of charge (SOC) of the battery with reference to a self-created OCV-SOC characteristic relationship, e.g., a table, curve, etc.

In particular, an aspect of the present disclosure includes a system for characterizing a lithium battery of a battery electric system. The system includes a sensor array, a processor, and a non-transitory computer-readable storage medium (“memory”). The sensor array is configured to measure a temperature-specific battery voltage and battery current of the battery as battery parameters. Instructions are executable by the processor from the memory to cause the processor to create a baseline open circuit voltage to state of charge characteristic relationship (“OCV-SOC relationship”) during a sequence of charging and discharging modes of the battery.

Instruction execution also causes the processor to determine, after creating and recording the baseline OCV-SOC relationship, whether the battery is in an open mode during which the battery is neither connected to a load nor charging. When the battery is in the open mode, the battery parameters are measured via the sensor array. An adjusted OCV-SOC relationship is generated by adjusting an SOC quantity of the baseline OCV-SOC relationship using the battery parameters. Execution of the instructions ultimately causes the processor to control an operation of the battery using the adjusted OCV-SOC relationship.

A method is also disclosed for characterizing a battery of a battery electric system. An embodiment of the method includes providing or creating a baseline OCV-SOC relationship during a sequence of charging and discharging modes of the battery, and determining, after creating the baseline OCV-SOC relationship, whether the battery is in an open mode during which the battery is not connected to a load. When the battery is in the open mode, the method includes measuring the battery parameters via the sensor array, generating an adjusted OCV-SOC relationship by adjusting an SOC quantity of the baseline OCV-SOC relationship using the battery parameters, and controlling operation of the battery using the adjusted OCV-SOC relationship.

Another aspect of the disclosure includes a battery electric system having a lithium battery, a load connectable to the lithium battery, a sensor array, and an electronic monitoring unit (EMU). The sensor array, which measures battery parameters of the battery, includes a voltage sensor operable for measuring a battery voltage, a current sensor operable for measuring a battery current, and a temperature sensor operable for measuring a battery temperature. The EMU is in communication with the lithium battery and the sensor array, and is configured to provide or create a baseline OCV-SOC relationship during a sequence of charging and discharging modes of the lithium battery.

The EMU in this embodiment also determines, after creating the baseline OCV-SOC relationship, whether the lithium battery is in an open mode during which the lithium battery is not connected to the load. When the lithium battery is in the open mode, the EMU measures the battery parameters via the sensor array, generates an adjusted OCV-SOC relationship by adjusting an SOC quantity of the baseline OCV-SOC relationship using the battery parameters, and ultimately controls operation of the lithium battery using the adjusted OCV-SOC relationship.

The above summary is not intended to represent every embodiment or aspect of the present disclosure. Rather, the foregoing summary exemplifies certain novel aspects and features as set forth herein. The above noted and other features and advantages of the present disclosure will be readily apparent from the following detailed description of representative embodiments and modes for carrying out the present disclosure when taken in connection with the accompanying drawings and the appended claims.

### BRIEF DESCRIPTION OF THE DRAWINGS

The drawings described herein are for illustrative purposes only, are schematic in nature, and are intended to be exemplary rather than to limit the scope of the disclosure.

FIG. 1 illustrates a battery electric system having a rechargeable battery and a battery monitoring system constructed in accordance with the present disclosure.

FIG. 2 is a schematic circuit diagram of the battery characterization system of FIG. 1 in accordance with a possible embodiment.

FIG. 3 is a time plot of battery voltage and open circuit voltage (OCV) for successive charging and open states of the battery.

FIG. 4 is a flow chart describing an embodiment of an autonomous method for characterizing the battery within the battery electric system of FIG. 1.

FIG. 5 is a representative OCV-SOC characteristic relationship for the lithium battery of FIG. 1.

FIG. 6 is a representative internal resistance vs. state of charge relationship for the lithium battery of FIG. 1.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

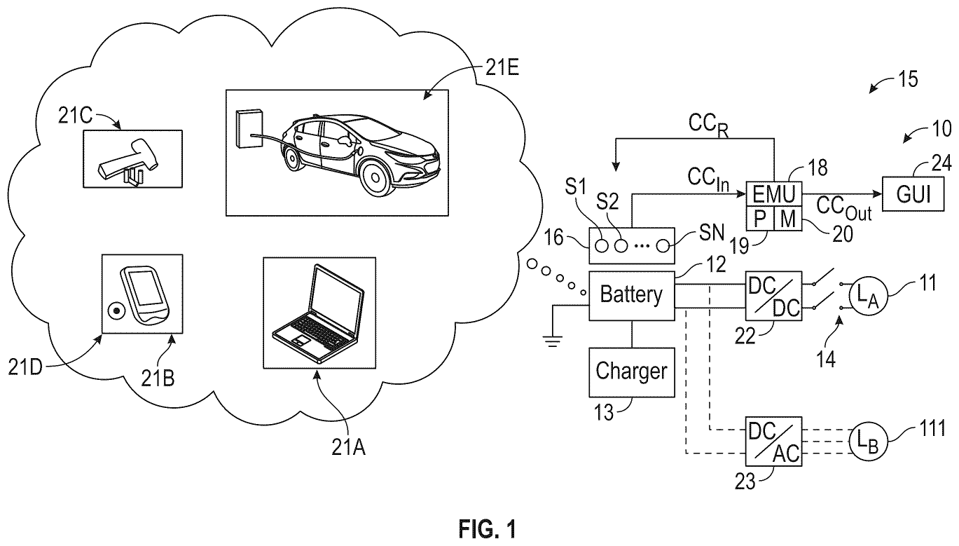

With reference to the drawings, wherein like reference numbers refer to the same or similar components throughout the several views, a battery electric system 10 is illustrated schematically in FIG. 1. The battery electric system 10 in a simplified embodiment includes a rechargeable electrochemical battery 12, characteristics of which are determined in real time and used to control the battery electric system 10 in accordance with the disclosure. As noted above, the battery 12 may be one of several different battery types, typically a lithium based battery as described herein. In such an embodiment, the battery 12 may be variously constructed as, e.g., a lithium cobalt oxide (LCO), lithium nickel manganese cobalt oxide (NMC), lithium iron phosphate (LFP), lithium nickel cobalt aluminum oxide (NCA), or lithium manganese oxide (LMO) battery or battery pack, to name just a few possibilities. Each battery type has unique performance characteristics providing relative advantages and disadvantages over competing battery types. The present strategy therefore autonomously characterizes the battery 12 while the battery 12 remains installed in the battery electric system 10 or other application set, creates a battery profile of at least an open circuit voltage and an internal resistance of the battery 12, and thereafter uses the generated battery profile to control operation of the battery 12 and the battery electric system 10.

As appreciated in the art, open circuit voltage (OCV) is the voltage capability of the battery 12 of FIG. 1 when an electric current does not flow between its positive/negative cathode and anode terminals. OCV is an equilibrium measurement that reflects the potential difference between the electrodes due to internal electrochemical reactions of the battery 12. OCV is used herein and in the art to estimate a state of charge (SOC) of the battery 12. Since OCV correlates with SOC, quantifying the OCV of the battery 12 can help determine a remaining charge of the battery 12, and thus inform charging/discharging control decisions within the battery electric system 10.

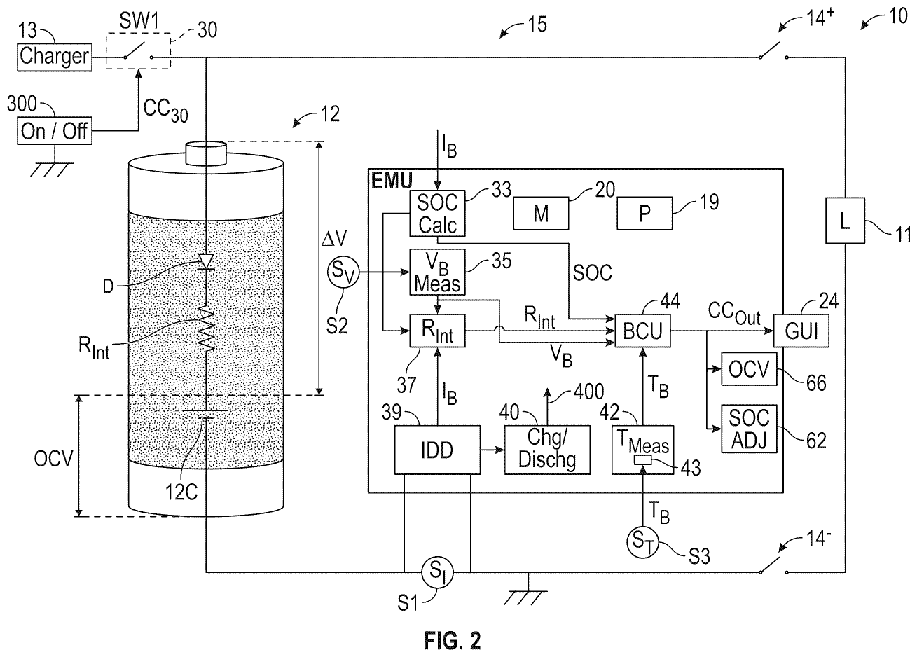

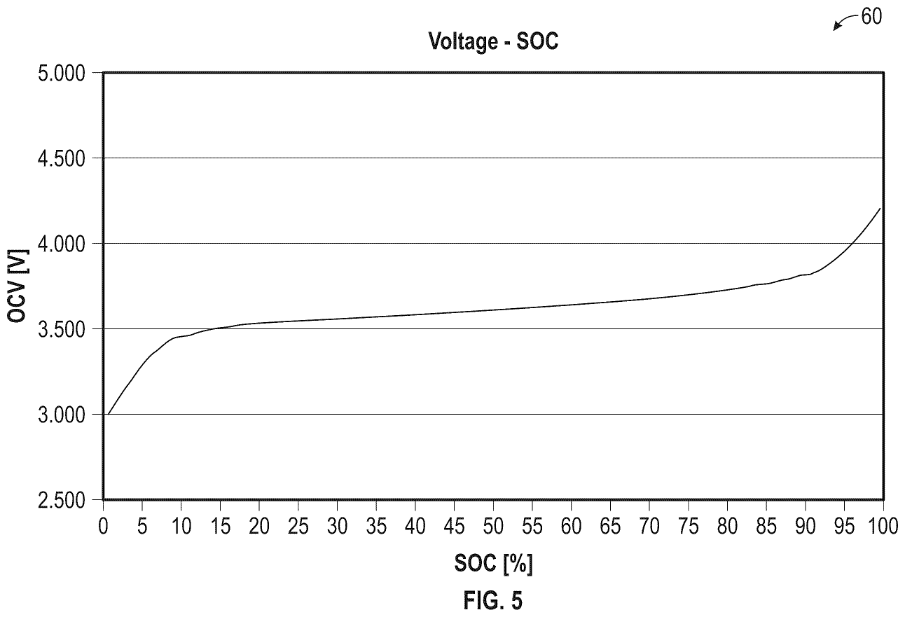

When the battery 12 is fully charged, the anode-to-cathode voltage difference (i.e., battery voltage V_{B}) is at its maximum. When looking at FIG. 2, V_{B}=ΔV+OCV. With no load and no charge, ΔV=0 and thus V_{B}=OCV. When the battery 12 is fully discharged, V_{B} is at its minimum. As OCV is not influenced by aging and temperature of the battery 12, it is a highly useful parameter for use in real-time battery monitoring, control, and state of health (SOH) evaluation. The present approach seeks to autonomously characterize OCV-SOC characteristics of the battery 12, thereby accommodating multiple different battery types and vendors. For a given temperature and voltage capacity, the OCV acts as a stable reference value for determining the above-noted anode-to-cathode voltage difference. As appreciated in the art, OCV, e.g., extracted from a recorded correlation or relationship, such as temperature-specific lookup table or curve referenced or indexed by SOC and OCV as in FIG. 5, may be used to determine the voltage shift difference (ΔV) by charge/load as a difference in measured battery voltage and OCV, i.e., ΔV=V_{B}−OCV.

The exemplary battery electric system 10 illustrated in FIG. 1 includes an electrical disconnect switch 14, a direct current (DC)-powered load (L_{A}) 11, and a battery monitoring system 15. The battery monitoring system 15 includes a sensor array 16 and an electronic monitoring unit (EMU) 18. The sensor array 16 is electrically connectable to the battery 12, for instance via one or more hard-wired transfer conductors and/or wireless pathways/network connections. As described below, the sensor array 16 configured to measure a temperature-specific battery voltage (V_{B}), current (I_{B}), and temperature (T_{B}) of the battery 12 as battery parameters.

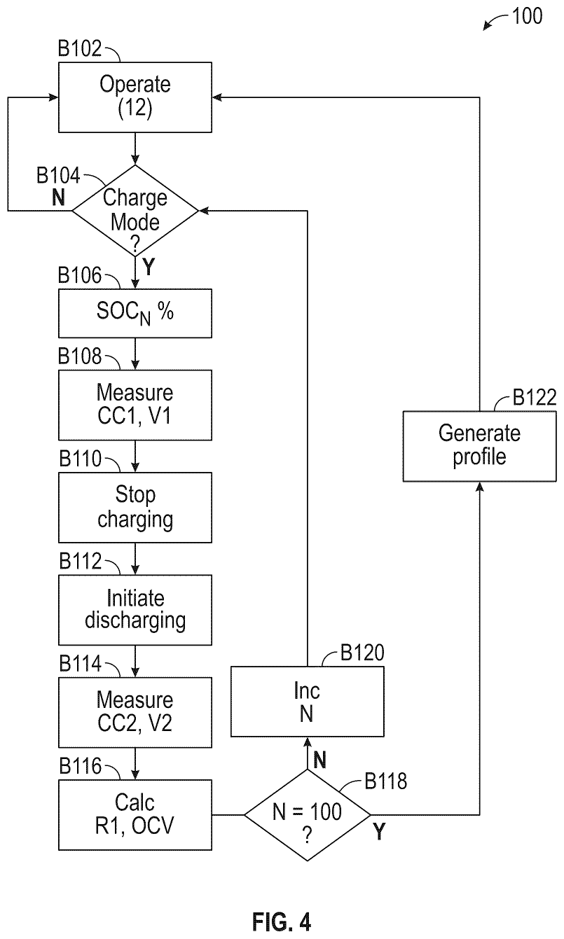

The EMU 18 of FIG. 1 in accordance with the present disclosure includes a processor (P) 19 and a non-transitory computer-readable storage medium (“memory”) (M) 20. The memory 20 includes instructions recorded thereon. The instructions are executable by the processor 19 to cause the processor 19 of the EMU 18 to perform a method 100, a non-limiting example implementation of which is described below with reference to FIG. 4. Among other actions, the EMU 18 may transmit a measurement request signal (CC_{R}) to the sensor array 16 to initiate battery monitoring.

In various implementations, the battery electric system 10 may be used as part of a mobile or stationary battery-powered device. For instance, the battery 12 may be used to power a portable electronic device such as a computer 21A, e.g., a tablet, desktop, or laptop computer, or a cellular phone 21B. Other applications may use the battery 12 as part of a medical device, for example a handheld surgical tool 21C or a wearable device 21D. The optional wearable device 21D may be constructed as a continuous glucose monitor (CGM) as shown, or alternatively as an automatic external defibrillator (AED), a blood oxygen monitor, or an infusion pump, among other possibilities.

Likewise, the battery 12 may be used to energize a mobile system 21E such as an electric vehicle, which is illustrated in FIG. 1 as it might appear when undergoing a battery charging process. Still other applications may be readily envisioned, including but not limited to electronic gaming systems, control consoles, or other industrial, medical, or transportation systems. The exemplary use, chemistry, construction, and simplified depiction of the battery 12 herein is therefore illustrative of the present teachings and non-limiting thereof unless otherwise specified.

The representative battery monitoring system 15 of FIG. 1 may include other components in different embodiments. For example, a direct current-to-direct current (DC-DC) converter 22 may be used with the battery 12 to increase or reduce the battery voltage before energizing the connected load 11. A battery charger 13 may be connectable to the battery 12 and used to recharge the battery 12 as needed. In an alternating current (AC) configuration of the battery electric system 10, the battery 12 may be connected to a DC-to-AC inverter circuit 23, with the inverter circuit 23 operable for outputting an AC waveform to a coupled AC-powered load (L_{B}) 111. The loads 11 and 111 may be variously embodied as electric motors, rotary actuators, linear actuators, displays, transducers, and/or other electrical or electromechanical devices depending on the application.

As part of the present battery monitoring strategy, various sensors S1, S2, . . . , SN of the sensor array 16 are used to measure or sense battery parameters during charging and discharging modes of the battery 12, with “N” being an integer representing an arbitrary N^{th} sensor in the sensor array 16. The battery parameters measured and used as part of the method 100 exemplified in FIG. 4 include at least a voltage, a current, and a temperature of the battery 12, with the EMU 18 of FIG. 1 also being configured to determine the state of charge (SOC) and an open-circuit voltage (OCV) of the battery 12 and its present charge/discharge state. The sensor array 16 may be integrated into a cell sense board (not shown) and connected to the battery 12 in a possible implementation.

Still referring to FIG. 1, input signals (CC_{IN}) from the sensor array 16 are communicated to the EMU 18 wirelessly and/or via physical transfer conductors. The EMU 18 thereafter outputs electronic control signals (CC_{OUT}) to a remote or external device 24, e.g., a graphical user interface (GUI) as labeled in FIG. 1, and/or a display screen, the disconnect switch 14, etc. The disconnect switch 14, which may be placed elsewhere in the schematic circuit of FIG. 1, including between the inverter circuit 23 and the AC-powered load 111 in such embodiments, may be variously embodied as electromechanical contactors or relays, e.g., solid state relays (SSRs), operable to disconnect the battery 12 under certain fault conditions.

Although omitted from FIG. 1 for illustrative simplicity and clarity, the battery electric system 10 may also be equipped with a thermal management system as summarized above to help regulate temperature of the battery 12 during its normal operation, for example cooling plates, fins, heat sinks, coolant conduit, etc. Likewise, other circuit components such as fuses may be implemented to ensure the safety and reliability of the battery electric system 10 during its operation.

In general, regardless of the battery type, the battery 12 when new/properly functioning will have a useable nominal usable capacity of 100% and a relatively low baseline internal resistance. Progressive aging, repeated charging/discharging, and deterioration of the battery 12 will eventually reduce its usable capacity and increase its internal resistance. In terms of general battery physics, charging operations of the battery 12 when configured as a lithium battery causes lithium ions to migrate within the battery 12 and become absorbed onto electrode surfaces. Abnormal growth and formation of unstable lithium deposits can result from repeated charging cycles and/or increased charging rates, e.g., during repeated DC fast-charging of the battery 12. Clusters of deposits can form elongated branch-like structures or dendrites. Dendrites and other lithium accumulations increase the internal resistance.

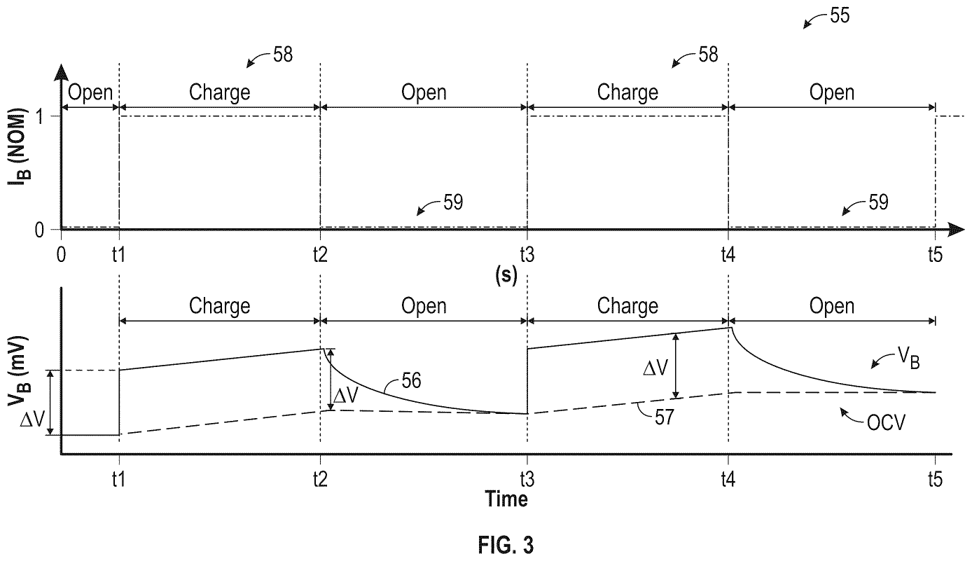

Referring to FIG. 2, portions of the battery electric system 10 of FIG. 1 are illustrated schematically as the battery monitoring system 15 and the load (L) 11. Open circuit voltage (OCV) is illustrated along with the internal resistance (R_{INT}) and voltage difference (ΔV). As shown in the representative parameter traces 55 of FIG. 3, measured battery voltage (V_{B}) in millivolts (mV) is illustrated along with a nominal battery current (I_{B}). Traces 56 and 57 of FIG. 3 represent the battery voltage and OCV during charging, i.e., nominal current level “1” (trace 58) and open (trace 59/nominal current level “0”) of the battery 12 for a given temperature.

The difference between traces 56 and 57 of FIG. 3 represents the above-noted voltage difference (ΔV) relative to a temperature-stable baseline, in this case the open circuit voltage (OCV). For a given temperature and capacity, in other words, OCV acts as a stable reference from which the voltage difference (ΔV) may be determined. As appreciated, the OCV, e.g., extracted from a temperature-specific lookup table referenced or indexed by SOC and OCV, may be used to determine the voltage difference (ΔV) as shown, for either charging or discharging modes. That is, ΔV is the difference in a measured battery voltage and the OCV, i.e., ΔV=V_{B}−OCV.

Referring again to FIG. 2, the battery 12 with an application specific number and configuration of battery cells 12C is disconnected from the load 11 during charging via opening of the disconnect switch 14, i.e., one or both disconnect switches 14⁺ and/or 14⁻, with + and − respectively indicating connection to positive and negative voltage rails of the battery electric system 10. An optional charging switch (SW1) 30 may be commanded to close, e.g., by the EMU 18 or another charging controller 300, as indicated by arrow CC₃₀ and corresponding label “ON/OFF”. This action electrically connects the battery 12 to the battery charger 13. The battery charger 13 may be connected to an offboard power supply (not shown), such as grid power. When the power supply is an AC outlet, the battery charger 13 includes an AC-to-DC converter operable to convert, filter, and output suitable DC voltage and current waveforms to the battery 12 for charging.

A current sensor (S_{I}) S1, which is a component of the sensor array 16 of FIG. 1 described above, may be used to detect the current flow direction and therefore help determine whether the battery 12 is in a charging mode or a discharging mode as the above-noted predetermined operating mode. The battery 12 is then removed from the battery charger 13 when the battery 12 is in use (discharging mode), with removal of the battery 12 from the battery charger 13 automatically opening the charging switch 30.

In a possible implementation of the EMU 18, corresponding hardware and software modules or blocks may be implemented to perform the requisite processing functions of the method 100 (see FIG. 4). A state of charge calculation (SOC Calc) block 33 may be used to determine the present SOC of the battery 12. The SOC calculation block 33 may be implemented in several ways, such as but not limited to Coulomb counting. Using such an approach, electric current flowing into and out of the battery 12 over time is closely tracked and integrated to determine the amount of transferred charge, as appreciated in the art. Other approaches may include, e.g., machine learning, voltage and temperature-based lookup tables, temperature-specific OCV-SOC characteristic tables or curves, or other possible approaches.

The EMU 18 of FIG. 2 may also include a voltage measurement block (V_{B} Meas) 35. This feature may be implemented using a voltage sensor (S_{V}) S2 of the sensor array 16 (FIG. 1), with the measured voltage (V_{B}) periodically measured and communicated to the voltage measurement block 35 and stored in non-volatile portions of the memory 20 of FIG. 1. An internal resistance calculation (R_{INT} Calc) block 37 receives the measured battery voltage (V_{B}) and uses this parameter to calculate the internal resistance (R_{INT}) as described below, along with a measured current value (I_{B}) from a current measurement block (IDD) 39. The current sensor S1 likewise measures and communicates a measured current value (I_{B}) to the internal resistance calculation block 37, and possibly to a charge/discharge detection block (CHG/DISCHG) 40 to determine when the battery 12 is charging or discharging. This may be accomplished by detecting the current flow direction through the battery 12. The charge/discharge detection block 40 may output a mode signal 400 indicative of the mode of the battery 12, i.e., whether the battery 12 is in an open mode or not. This information is used by the EMU 18 in the performance of the method 100 as described below.

The EMU 18 illustrated in FIG. 2 also considers battery temperature (T_{B}) in evaluating the degradation level and state of health (SOH) of the battery 12. To that end, the EMU 18 may be equipped with a temperature measurement block (Temp Meas) 42 which is in communication with a temperature sensor (S_{T}) S3, e.g., a thermistor or thermocouple. The measured battery temperature (T_{B}) may be requested by, communicated to, and recorded by the temperature measurement block 42, possibly with assistance of an analog-to-digital converter 43.

The measured battery temperature (T_{B}) is then communicated to a battery characterization unit (BCU) 44 operable for characterizing the battery 12, with inputs to the BCU 44 including the calculated SOC from SOC calculation block 33, the measured battery voltage levels (V_{B}) from the voltage measurement block 35, and the calculated internal resistance (R_{INT}) from internal resistance calculation block 37. As part of the present approach, the EMU 18 also responds to characterization of the battery 12 by updating a baseline OCV-SOC relationship 60 (FIG. 5) as needed, along with adjusting an SOC level of the battery 12 as needed, with the latter achieved using an SOC adjustment unit (SOC Adj Unit) 62.

In one or more embodiments, the EMU 18 of FIG. 2 may generate or be requested to generate alerts via communication of the output signals (CC_{OUT}) to the external device/GUI 24. Depending on the application, the alerts may entail audible alarms, indicator lights, text messages, haptic feedback, and the like, which may include a request to discard or replace the battery 12.

Referring to FIG. 4, an embodiment of a method 100 is illustrated using a series of code segments, algorithms, or logic blocks for simplicity and clarity. The logic blocks may be executed by the processor 19 of FIGS. 1 and 2 during operation of the battery electric system 10 to characterize the battery 12, and to create a battery profile of the OCV and internal resistance (R_{INT}) of the battery 12. This is achieved without removing the battery 12 from the battery electric system 10. As noted above, different battery types have different OCV-SOC relationships. Performance of the method 100 helps ensure that this relationship is accurately determined for the particular chemistry of the battery 12, which may change over time when different battery types are used, and tracked during operation of the battery electric system 10.

In general, the method 100 may be performed by the processor 19 of FIGS. 1 and 2 when the processor 19 executed instructions from memory 20. Doing so may cause the processor 19 to create (or access) a baseline OCV-SOC relationship during a sequence of charging and discharging modes of the battery 12, and then determine, after creating the baseline OCV-SOC relationship, whether the battery 12 is in an open mode during which the battery 12 is not connected to the load 11 or 111. When the battery 12 is in the open mode, the processor 19 measures/commands measurement of the battery parameters via the sensor array 16 and generates an adjusted OCV-SOC relationship. This may entail adjusting an SOC quantity of the baseline OCV-SOC relationship, e.g., FIG. 5, using the battery parameters. The processor 19 thereafter controls operation of the battery 12 using the adjusted OCV-SOC relationship. Also, approaches described herein proceed with the assumption that absolute current value is measurable and available. As appreciated in the art, alternative approaches may be used to extract OCV and internal resistance using external load resistance and the resistance of the load switching.

A representative embodiment of the method 100 commences with block B102 (“Operate (12)”). The method 100 may include initiating use of the battery 12 within the battery electric system 10. The battery 12 is turned on so that the load 11 (FIGS. 1 and 2) may be energized as needed by discharging of the battery 12. The method 100 then proceeds to block B104.

Block B104 (“Charge Mode?”) entails determining, via the processor 19, whether the battery 12 is currently in a charging mode. This determination may be made using the charge/discharge detection block 40 of FIG. 2 as described above, i.e., by processing the mode signal 400. The method 100 proceeds to block B106 when the battery 12 is in the charging mode, with the method 100 instead returning to block B102 when the battery 12 is not charging.

Block B106 (“SOC_{N}%”) of FIG. 4 includes loading current from the battery 12 to a cut-off voltage, e.g., about 3.0V for the exemplary battery cell 12C of FIG. 2, and commencing charging from 0% SOC, or N−1 for this iteration, where N is an integer counter value. Concurrently with charging, the EMU 18 of FIG. 2 starts the SOC monitoring function of SOC calculation block 33, e.g., via Coulomb counting. The method 100 then proceeds to block B108.

At block B108 (“Measure CC1, V1”), the EMU 18 measures the battery current (CC1) and the battery voltage (V_{B}), in this instance referred to as V1, at SOC=N, with N=1% in the first iteration of method 100, or another selectable predetermined percentage step. That is, starting with a first SOC of 0%, each SOC of a sequence of progressively higher SOCs in this example implementation is 1% higher than a next-lowest SOC and 1% lower than a next-highest SOC. In other embodiments, each successive SOC is selectable as a predetermined percentage step, i.e., not necessarily equal to 1%. The method 100 then proceeds to block B110.

At block B108 (“Stop Charging”), the EMU 18 next commands cessation of the charging operation. The method 100 thereafter proceeds to block B112.

Block B112 (“Init Discharging”) of FIG. 4 entails discharging battery current to the load 11. The method 100 thereafter proceeds to block B114.

Block B114 (“Measure CC2, V2”) includes using the EMU 18 to measure the load current (LC2) and voltage (V2) at SOC=N during discharging, with N=1% in the first iteration of method 100. The method 100 then proceeds to block B116.

Block B116 (“Calc R1, OCV”) includes calculating the internal resistance (R_{INT}) and OCV for SOC=1%, with the EMU 18 doing so using the values from the preceding blocks. The values are recorded in non-volatile portions of the memory 20. The method 100 then proceeds to block B118.

At block B118 (“N=100?”), the EMU 18 determines whether the counter value (N)=100, which would indicate that all voltage and current measurements have been collected for SOC =1%, 2%, 3%, 4%, . . . , all the way up to 100% (or another % step value in other implementations). The method 100 proceeds to block B120 when N≠100, and to block B122 in the alternative when N=100.

At block B120 (“Inc N”), the EMU 18 increments the counter value (N). Thus, after a first iteration of the method 100 at SOC=1%, N will be increased from 1 to 2, then from 2 to 3, and so forth. The method 100 thereafter returns to block B104.

Block B122 (“Generate Profile”) includes generating a battery profile for the battery 12 of FIGS. 1 and 2 using the data from multiple iterations of the method 100, i.e., from charge and discharge cycles corresponding to SOC=1%, and by 1% increments up to and including to SOC=100% (or other % step values in other embodiments). With knowledge of SOC and the OCV at each SOC (1% to 100%), for instance, the EMU 18 may easily construct the OCV relationship of trace 60 (FIG. 5) and save to non-volatile portions of the memory 20.

While 1% SOC increments are used in the non-limiting example embodiment of the method 100 to create a baseline OCV-SOC relationship, the instructions in other embodiments may be executable by the processor 19 to cause the processor 19 to create the baseline OCV-SOC relationship by charging the battery beginning at a first SOC, the when the SOC reaches the first SOC, measuring the battery parameters using the sensor array 16. The battery 12 may be discharged after measuring the battery parameters at the first SOC. While discharging the battery 12 from the first SOC, the battery parameters may be measured again using the sensor array 16. Repeating charging and discharging of the battery 12 may occur with measuring of the battery parameters using the sensor array 16 for a plurality of progressively higher SOCs relative to the first SOC. The baseline OCV-SOC relationship for the battery 12 may thereafter be created using the battery parameters for each respective SOC.

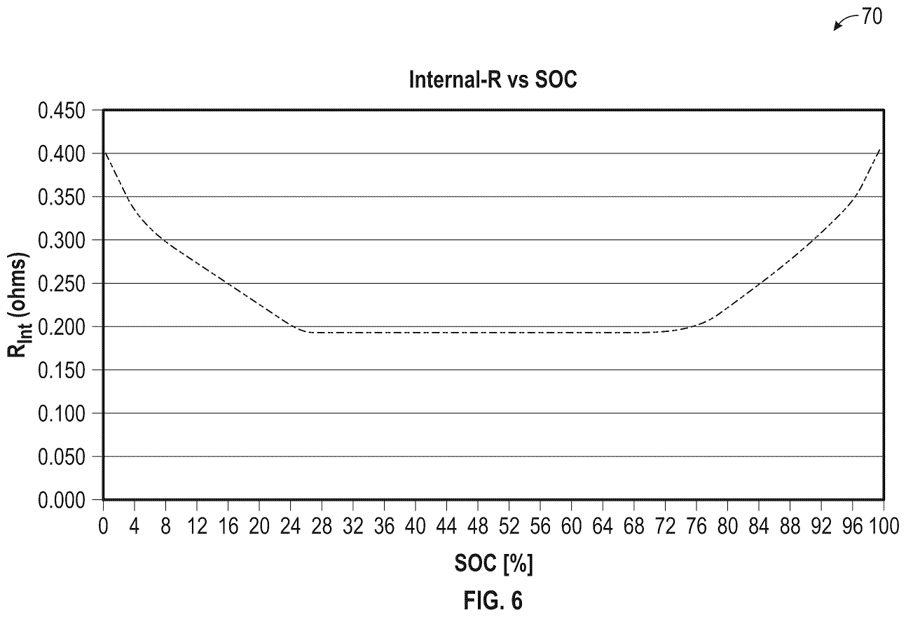

Referring briefly to FIG. 6, at each respective SOC in the range 1-100%, the EMU 18 also records the internal resistance (R_{INT}). This information is then saved to non-volatile memory as trace 70, either as a curve as illustrated or as a lookup table. As shown in FIG. 6, internal resistance varies with SOC in a unique manner for each battery type. Internal resistance may be relatively high, e.g., 0.4Ω, at SOC=0% and SOC=100%. As SOC rises toward about 25% in this example, the internal resistance may decrease to about half of its maximum, or about 0.2 Ω in the non-limiting example of FIG. 6. Internal resistance may plateau in its middle band, i.e., SOC=25% to 75%, before again rising to its maximum between SOC 75% to 100%. The shape/trajectory of trace 70 varies with the battery type, and thus determination of trace 70, i.e., the internal resistance vs. SOC relationship, is part of the battery characterization process described herein. The EMU 18 may therefore determine internal resistance of the battery 12 for the each respective SOC of N=1% to 100% using the battery parameters collected by the sensor array 16, and then execute a control action based on the internal resistance of the battery 12 as described herein.

Alternatives to the method 100 may entail incrementally charging the battery 12 in 1% SOC increments, as before. However, after each charging increment the EMU 18 may pause for a suitable wait time until OCV reaches a true steady-state value. At this point, the EMU 18 could command the sensor suite 16 to measure and report the battery voltage V1 and current CC1 at SOC=N %, with N=1% in the first iteration, before proceeding in the same manner for N=2, 3, . . . , 100.

Regarding wait time, this may be seen in FIG. 3 when charging stops at t₂ and t₄, with the decay in trace 56 and gradual settling of trace 57 (OCV) until t₃ and t₅. It may be necessary to wait a long time for the OCV to reach its steady state value with incremental charging. Such waiting is not required in the method 100 described above.

Embodiments of the method 100 may also adjust a predetermined/baseline version of the OCV relationship 60 (FIG. 5) and internal resistance relationship (FIG. 6) via the EMU 18. For a representative lithium-ion construction of the battery 12, for example, a baseline relationship may be recorded in memory 20 for a specific lithium type, with real-time adjustment by the EMU 18 to SOC or other parameters based on observed characteristics of the battery 12 during performance of the method 100. Thereafter, the saved traces 60 and 70 of respective FIGS. 5 and 6 may be used by the ECU 18 to control a state of the battery 12.

The functions of method 100 may be embodied as computer-readable instructions and executed from the memory 20, for instance magnetic or optical media, CD-ROM, and/or solid-state/semiconductor memory (e.g., diverse types of RAM or ROM). The processor 19 may encompass one or more control modules, control units, microprocessor chips, Application Specific Integrated Circuit(s) (ASIC), Field-Programmable Gate Array(s) (FPGA(s)), electronic circuit(s), or central processing units. Associated memory component(s) of the memory 20 include non-transitory computer-readable storage devices such as read only memory, programmable read only memory, hard drive, etc. Non-transitory components of the memory 20 used herein are capable of storing machine-readable instructions in the form of one or more software or firmware programs or routines, combinational logic circuit(s), input/output circuit(s) and devices, signal conditioning and buffer circuitry and other components that can be accessed by one or more of the processors 19 to provide a described functionality.

Using the method 100, the battery 12 of FIGS. 1 and 2 may be autonomously characterized by the EMU 18 using its BCU 44 (FIG. 2) while the battery 12 remains installed in the battery electric system 10. The solutions presented herein may use the BCU 44 to determine internal resistance (R_{INT}) of the battery 12 for each incremental SOC, i.e., 1% to 100%, then record the relationship in non-volatile memory portions of the memory 20. In the described implementation, the method 100 may include charging the battery 12 beginning at an SOC of 0%. When the SOC reaches 1%, the method 100 may include measuring the battery parameters using the sensor array 16, then discharging the battery 12. While discharging the battery 12 from 1%, the method 100 includes measuring the battery parameters using the sensor array 16. For each respective SOC of N=1% to 100%, where N is an integer as noted above, the method 100 may include repeating charging and discharging of the battery 12 and measuring the battery parameters using the sensor array 16 each time. The baseline OCV-SOC relationship may be created for the battery 12 using the battery parameters for each respective SOC.

As appreciated in the art, such information may be used by the EMU 18 to estimate the state of health (SOH) of the battery 12, among other possible actions. For example, instructions may be executable by the processor 19 of FIGS. 1 and 2 to cause the processor 19 to determine a numeric SOH of the battery 12 using the internal resistance (R_{INT}) of the battery 12. The EMU 18 may execute a control action when the numeric SOH of the battery 12 is less than a threshold SOH, for instance by transmitting an SOH notice to the external device/GUI 24 of FIGS. 1 and 2. That is, once the internal resistance vs. SOC relationship of the battery 12 has been accurately established, the EMU 18 may monitor trends in this relationship over time to determine the SOH of the battery 12, e.g., as a numeric SOH value ranging from fully depleted (e.g., SOH=0) to fully healthy (e.g., SOH=100). The above-noted SOH threshold in this instance may be set at a desired level, e.g., SOH=50% or SOH=25%, to provide sufficient time to service or replace the battery 12.

While several modes for carrying out the many aspects of the present teachings have been described in detail, those familiar with the art to which these teachings relate will recognize various alternative aspects for practicing the present teachings that are within the scope of the appended claims. The above description and accompanying drawings are illustrative and exemplary of the entire range of alternative embodiments that an ordinarily skilled artisan would recognize as implied by, structurally and/or functionally equivalent to, or otherwise rendered obvious based upon the included content, and not as limited solely to those explicitly depicted and/or described embodiments. Moreover, the present concepts expressly include combinations and sub-combinations of the described elements and features. The detailed description and the drawings are supportive and descriptive of the present teachings, with the scope of the present teachings defined solely by the claims.

What is claimed is:

1. A system for characterizing a battery of a battery electric system, the system comprising:
a sensor array configured to measure a temperature-specific battery voltage and battery current of the battery as battery parameters;
a processor; and
a non-transitory computer-readable storage medium (“memory”), the memory including instructions, the instructions being executable by the processor to cause the processor to:
providing a baseline open circuit voltage to state of charge (OCV-SOC) relationship;
determine whether the battery is in an open mode during which the battery is not connected to a load;
when the battery is in the open mode, measuring the battery parameters via the sensor array;
generating an adjusted OCV-SOC relationship by adjusting an SOC quantity of the baseline OCV-SOC relationship using the battery parameters;
and controlling operation of the battery using the adjusted OCV-SOC relationship.

2. The system of claim 1, wherein the instructions are executable by the processor to cause the processor to provide the baseline OCV-SOC relationship by:
charging the battery beginning at a relatively low first SOC;
when the SOC reaches the first SOC, measuring the battery parameters using the sensor array;
discharging the battery after measuring the battery parameters at the first SOC;
while discharging the battery from the first SOC, measuring the battery parameters using the sensor array;
repeating charging and discharging of the battery and measuring the battery parameters using the sensor array for a plurality of progressively higher SOCs relative to the first SOC; and
creating the baseline OCV-SOC relationship for the battery using the battery parameters for each respective SOC.

3. The system of claim 2, wherein the instructions are executable by the processor to cause the processor to:
determine an internal resistance of the battery using the battery parameters for the first SOC and each of the progressively higher SOCs; and
execute a control action based on the internal resistance of the battery.

4. The system of claim 3, wherein the instructions are executable by the processor to cause the processor to:
determine a numeric state of health (SOH) of the battery using the internal resistance of the battery; and
execute the control action when the numeric SOH of the battery is less than a threshold SOH.

5. The system of claim 1, wherein the control action includes transmitting an SOH notice or message to an external device.

6. The system of claim 1, wherein the instructions are executable by the processor to cause the processor to monitor the SOC using an SOC monitoring unit while charging the battery.

7. The system of claim 6, wherein the SOC monitoring unit is configured to perform a Coulomb counting process.

8. The system of claim 1, wherein the battery is a lithium battery.

9. A method for characterizing a battery of a battery electric system, the method comprising:
providing a baseline open circuit voltage to state of charge (OCV-SOC) relationship;
determining whether the battery is in an open mode during which the battery is not connected to a load;
when the battery is in the open mode, measuring battery parameters via a sensor array;
generating an adjusted OCV-SOC relationship by adjusting an SOC quantity of the baseline OCV-SOC relationship using the battery parameters; and
controlling operation of the battery using the adjusted OCV-SOC relationship.

10. The method of claim 9, wherein providing the baseline OCV-SOC relationship includes creating the baseline OCV-SOC relationship by:
charging the battery beginning at a relatively low first SOC;
when the SOC reaches the first SOC, measuring the battery parameters using the sensor array;
discharging the battery after measuring the battery parameters at the first SOC;
while discharging the battery from the first SOC, measuring the battery parameters using the sensor array;
repeating charging and discharging of the battery and measuring the battery parameters using the sensor array for a plurality of progressively higher SOCs relative to the first SOC; and
creating the baseline OCV-SOC relationship for the battery using the battery parameters for each respective SOC.

11. The method of claim 10, wherein the first SOC is 0%, and wherein each successive SOC of the progressively higher SOCs is selectable as a predetermined percentage step.

12. The method of claim 10, further comprising:
determining an internal resistance of the battery using the battery parameters;
determining a numeric state of health (SOH) of the battery using the internal resistance of the battery; and
executing the control action when the numeric SOH of the battery is less than a threshold SOH.

13. The method of claim 12, wherein executing the control action includes transmitting an SOH notice or message to an external device.

14. The method of claim 9, further comprising:
monitoring the SOC in real-time using an SOC monitoring unit while charging the battery, including performing a Coulomb counting process via the SOC monitoring unit.

15. A battery electric system, comprising:
a lithium battery connectable to a load;
a sensor array configured to measure battery parameters of the battery, the sensor array including a voltage sensor operable for measuring a battery voltage, a current sensor operable for measuring a battery current, and a temperature sensor operable for measuring a battery temperature; and
an electronic monitoring unit (EMU) in communication with the lithium battery and the sensor array, the EMU being configured to:
provide a baseline open circuit voltage to state of charge (OCV-SOC) characteristic relationship;
determine whether the lithium battery is in an open mode during which the lithium battery is not connected to the load;
when the lithium battery is in the open mode, measure the battery parameters via the sensor array;
generate an adjusted OCV-SOC characteristic relationship by adjusting an SOC quantity of the baseline OCV-SOC characteristic relationship using the battery parameters; and
control operation of the lithium battery using the adjusted OCV-SOC characteristic relationship.

16. The battery electric system of claim 15, wherein the ECU is configured to:
determine, using the battery parameters, an internal resistance of the battery for each of a plurality of SOC of the battery; and
execute a control action based on the internal resistance of the battery.

17. The battery electric system of claim 16, wherein the ECU is configured to:
determine a numeric state of health (SOH) of the battery using the internal resistance of the battery; and
execute the control action when the numeric SOH of the battery is less than a threshold SOH.

18. The battery electric system of claim 17, wherein the control action includes transmitting an SOH notice to an external device indicative of the numeric SOH.

19. The battery electric system of claim 17, wherein the EMU is configured to monitor the SOC using an SOC monitoring unit while charging the lithium battery.

20. The battery electric system of claim 19, wherein the SOC monitoring unit is configured to monitor the SOC by performing a Coulomb counting process.
